(19) United States
(12) Patent Application Publication
(10) Pub. No.: US 2017/0311485 A1
(43) Pub. Date: Oct. 26, 2017

(54) COOLING DEVICE AND METHOD OF MANUFACTURING THE SAME

(71) Applicant: NEC Corporation, Tokyo (JP)

(72) Inventors: Minoru YOSHIKAWA, Tokyo (JP); Akira SHOUJIGUCHI, Tokyo (JP); Masaki CHIBA, Tokyo (JP); Arihiro MATSUNAGA, Tokyo (JP); Masanori SATO, Tokyo (JP)

(21) Appl. No.: 15/514,081

(22) PCT Filed: Sep. 15, 2015
(86) PCT No.: PCT/JP2015/004700

§ 371 Date: Mar. 24, 2017

(30) Foreign Application Priority Data
Sep. 26, 2014 (JP) 2014-196175

(51) Int. Cl. H05K 7/20; B23P 15/26

(52) U.S. Cl. CPC H05K 7/20663; B23P 15/26

(57) ABSTRACT

It is impossible to avoid the increase in device cost and maintenance cost in order to cool a heat source efficiently using a natural-circulation type phase-change cooling device; therefore, a cooling device according to an exemplary aspect of the present invention includes a heat receiving unit for receiving heat; a condensing unit for releasing heat; and a refrigerant intermediary unit for connecting the heat receiving unit with the condensing unit, and transporting refrigerant circulating between the heat receiving unit and the condensing unit, wherein the refrigerant intermediary unit includes a refrigerant retaining unit for retaining the refrigerant, a primary tube connecting the refrigerant retaining unit with the condensing unit, and a secondary tube connecting the refrigerant retaining unit with the heat receiving unit and including a bendable tube.

### TECHNICAL FIELD

The present invention relates to cooling devices used for cooling electronic appliances and methods of manufacturing the cooling devices and, in particular, to a cooling device with a natural-circulation type in which refrigerant vapor resulting from a phase change by receiving heat is transported without a driving source and condensed, and a method of manufacturing the cooling device.

### BACKGROUND ART

In recent years, the required amount of information processing has increased with the improvement in information processing technologies and the rise of the Internet environment. Data centers (DCs) are installed and operated in various places in order to process huge volumes of data. Here, the data center (DC) means a specialized facility for installing and operating severs and data communication devices. In the data centers (DCs), the density of heat generation by electronic devices such as a server and a data communication device is extremely high; consequently, it is necessary to cool these electronic devices efficiently.

A natural-circulation type phase-change cooling system has been known as an example of efficient cooling systems for electronic devices and the like (see, Patent Literature 1, for example). In the natural-circulation type phase-change cooling system, the heat generated by a heat source such as an electronic device is received and released using the latent heat of refrigerant. This system makes it possible to drive the refrigerant circularly without power supply because of the buoyancy of refrigerant vapor and the gravity of refrigerant liquid. Accordingly, the natural-circulation type phase-change cooling system enables efficient and energy-saving cooling of electronic devices and the like.

An example of a natural-circulation type phase-change cooling device is described in Patent Literature 1. A related cooling system disclosed in Patent Literature 1 includes evaporators set respectively in a plurality of servers, a cooling tower installed on the roof of a building, a return pipe (refrigerant gas pipe), and a supply pipe (refrigerant liquid pipe). The return pipe and the supply pipe connect cooling coils set in the evaporators to a spiral pipe set in the cooling tower. The return pipe returns the refrigerant gas vaporized in the evaporators to the cooling tower. The supply pipe supplies the evaporators with the refrigerant liquid that is liquefied resulting from cooling and condensing the refrigerant gas in the cooling tower. This forms a circulation line through which the refrigerant circulates naturally, between the evaporators and the cooling tower.

Each evaporator is provided with a temperature sensor to measure the temperature of the air that results from cooling, in the evaporator, the high temperature air exhausted from a server. At the outlet of the cooling coil in each of the evaporators, a valve (flow adjustment means) is provided that adjusts the supply flow rate of the refrigerant supplied to the cooling coil (refrigerant flow). A controller automatically adjusts the degree of opening of each valve based on the temperature measured by the temperature sensor. This enables the supply flow rate of the refrigerant to decrease by narrowing the opening of the valve if the temperature of the air that has been cooled in the evaporators becomes too lower than a predetermined temperature.

It is said that, according to the related cooling system, the above-described configuration keeps the supply flow rate of the refrigerant in each evaporator from increasing more than necessary; accordingly, it is possible to reduce the cooling load of the refrigerant and achieve a sufficient cooling performance by using a cooling tower only.

### CITATION LIST

### Patent Literature

[PTL 1] Japanese Unexamined Patent Application Publication No. 2009-194093 (paragraphs [0047]-[0055], FIG. 1)

### SUMMARY OF INVENTION

### Technical Problem

As mentioned above, the related cooling system disclosed in Patent Literature 1 is configured to include valves respectively to adjust the supply flow rate of the refrigerant supplied to the cooling coils that are disposed in the evaporators, and to adjust automatically the degree of opening of each valve based on the temperature of the air that has been cooled in the evaporators. That is to say, a computerized valve is disposed at the outlet of the evaporator and made to operate simultaneously with the temperature sensor, by which an appropriate amount of refrigerant liquid is supplied to the evaporator depending on the load of the server rack. The reason is that the phase change is inhibited due to the pressure of the refrigerant liquid if there is too much fluid volume of the refrigerant liquid in the evaporator, which results in conventional liquid cooling by sensible heat, not by latent heat with large amount of heat transfer. The reason is that it becomes difficult to perform the phase-change cooling efficiently because it is impossible to absorb the heat without the phase change arising if the fluid volume of the refrigerant liquid becomes insufficient in contrast.

However, because the related cooling system is configured to include a valve in each of the plurality of evaporators, there has been the problem that the related cooling system requires the cost not only of devices including a valve control system but also of the maintenance for stable operation.

Thus, there has been the problem that it is impossible to avoid the increase in device cost and maintenance cost in order to cool a heat source efficiently using a natural-circulation type phase-change cooling device.

The object of the present invention is to provide a cooling device and a method of manufacturing the cooling device that solve the above-mentioned problem that it is impossible to avoid the increase in device cost and maintenance cost in order to cool a heat source efficiently using a natural-circulation type phase-change cooling device.

### Solution to Problem

A cooling device according to an exemplary aspect of the present invention includes a heat receiving unit for receiving heat; a condensing unit for releasing heat; and a refrigerant intermediary unit for connecting the heat receiving unit with the condensing unit, and transporting refrigerant circulating between the heat receiving unit and the condensing unit, wherein the refrigerant intermediary unit includes a refrigerant retaining unit for retaining the refrigerant, a primary tube connecting the refrigerant retaining unit with the condensing unit, and a secondary tube connecting the refrigerant retaining unit with the heat receiving unit and including a bendable tube.

A method of manufacturing a cooling device according to an exemplary aspect of the present invention includes disposing a heat receiving unit for receiving heat; disposing a condensing unit for releasing heat on a ceiling panel; disposing a refrigerant retaining unit for retaining refrigerant below the condensing unit and above the heat receiving unit; connecting the refrigerant retaining unit with the condensing unit by a primary tube; and connecting the refrigerant retaining unit with the heat receiving unit by a secondary tube including a bendable tube.

### Advantageous Effects of Invention

According to the cooling device and the method of manufacturing the cooling device of the present invention, it is possible to cool a heat source efficiently employing a natural-circulation type phase-change cooling system without the increase in device cost and maintenance cost.

### BRIEF DESCRIPTION OF DRAWINGS

FIG. 1 is a schematic view illustrating a configuration of a phase-change cooling device according to a first example embodiment of the present invention.

FIG. 2 is a side view illustrating a configuration of a part of the phase-change cooling device according to the first example embodiment of the present invention.

FIG. 3A is a top view illustrating a configuration of a part of the phase-change cooling device according to the first example embodiment of the present invention, with the rear door of the electronic equipment rack closed.

FIG. 3B is a top view illustrating a configuration of a part of the phase-change cooling device according to the first example embodiment of the present invention, with the rear door of the electronic equipment rack open.

FIG. 4 is a side view illustrating another configuration of a part of the phase-change cooling device according to the first example embodiment of the present invention.

FIG. 5A is a top view illustrating another configuration of a part of the phase-change cooling device according to the first example embodiment of the present invention, with the rear door of the electronic equipment rack closed.

FIG. 5B is a top view illustrating another configuration of a part of the phase-change cooling device according to the first example embodiment of the present invention, with the rear door of the electronic equipment rack open.

FIG. 6 is a front view illustrating yet another configuration of a part of the phase-change cooling device according to the first example embodiment of the present invention.

FIG. 7 is a schematic view illustrating a configuration of a phase-change cooling device according to a second example embodiment of the present invention.

FIG. 8A is a front view illustrating a specific configuration of the phase-change cooling device according to the second example embodiment of the present invention.

FIG. 8B is a top view illustrating a specific configuration of the phase-change cooling device according to the second example embodiment of the present invention.

FIG. 9 is a front view illustrating another configuration of the phase-change cooling device according to the second example embodiment of the present invention.

FIG. 10A is a front view illustrating yet another configuration of the phase-change cooling device according to the second example embodiment of the present invention.

FIG. 10B is a top view illustrating yet another configuration of the phase-change cooling device according to the second example embodiment of the present invention.

FIG. 11A is a top view illustrating a configuration of a phase-change cooling device according to a third example embodiment of the present invention.

FIG. 11B is a side view illustrating a configuration of the phase-change cooling device according to the third example embodiment of the present invention.

FIG. 12 is a front view illustrating another configuration of the phase-change cooling device according to the third example embodiment of the present invention.

FIG. 13A is a top view illustrating yet another configuration of the phase-change cooling device according to the third example embodiment of the present invention.

FIG. 13B is a side view illustrating yet another configuration of the phase-change cooling device according to the third example embodiment of the present invention.

FIG. 13C is a front view illustrating yet another configuration of the phase-change cooling device according to the third example embodiment of the present invention.

### EXAMPLE EMBODIMENT

Example embodiments of the present invention will be described with reference to drawings below.

### A First Example Embodiment

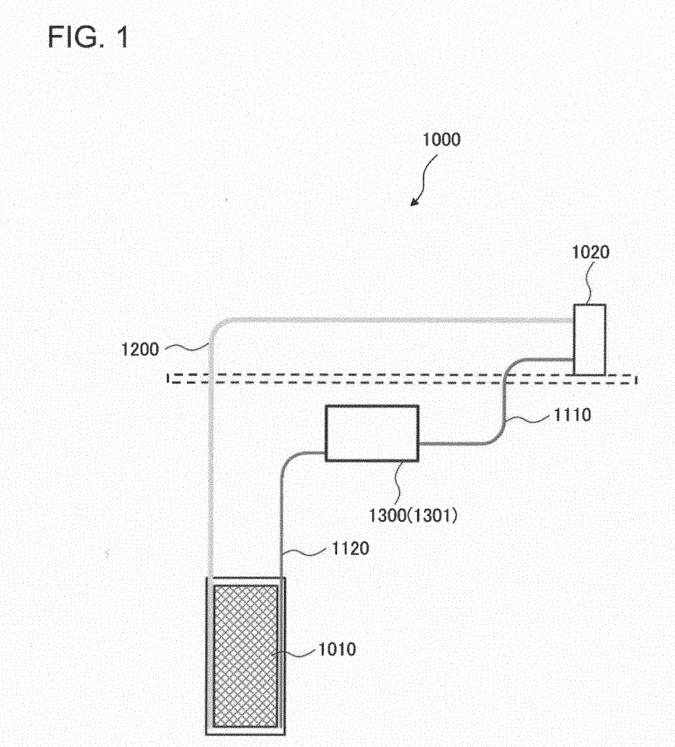

FIG. 1 is a schematic view illustrating a configuration of a phase-change cooling device 1000 that serves as a cooling device according to the present example embodiment. The phase-change cooling device 1000 according to the present example embodiment includes a heat receiving unit 1010, a condensing unit 1020, and a refrigerant transporting structure.

The heat receiving unit 1010 contains refrigerant to receive heat from a heat source. The condensing unit 1020 condenses and liquefies refrigerant vapor of the refrigerant evaporated in the heat receiving unit 1010 and generates refrigerant liquid.

The refrigerant transporting structure (refrigerant intermediary unit) connects the heat receiving unit 1010 with the condensing unit 1020, and transports the refrigerant circulating between the heat receiving unit 1010 and the condensing unit 1020. More specifically, the refrigerant transporting structure transports and conveys the refrigerant evaporated in the heat receiving unit 1010 (refrigerant vapor) and the refrigerant condensed and liquefied in the condensing unit 1020 (refrigerant liquid), in the course of circulating between the heat receiving unit 1010 and the condensing unit 1020. The refrigerant transporting structure includes a refrigerant retaining unit 1300 for retaining the refrigerant, a primary tube 1110 connecting the refrigerant retaining unit 1300 with the condensing unit 1020, and a secondary tube 1120 connecting the refrigerant retaining unit 1300 with the heat receiving unit 1010 and including a bendable tube (flexible tube). As illustrated in FIG. 1, the refrigerant retaining unit 1300 is located below the condensing unit 1020 and above the heat receiving unit 1010.

FIG. 1 illustrates a case where the refrigerant retaining unit 1300 is a refrigerant liquid reservoir 1301 to store the refrigerant liquid. Because the refrigerant liquid reservoir 1301 can store the refrigerant liquid temporarily, it can compensate for the excess or deficiency of the refrigerant liquid flowing back to the heat receiving unit 1010. Here, the primary tube 1110 is a primary liquid tube through which the refrigerant liquid mainly flows, and the secondary tube 1120 is a secondary liquid tube through which the refrigerant liquid mainly flows. The refrigerant transporting structure includes a vapor tube 1200 through which the refrigerant vapor mainly flows.

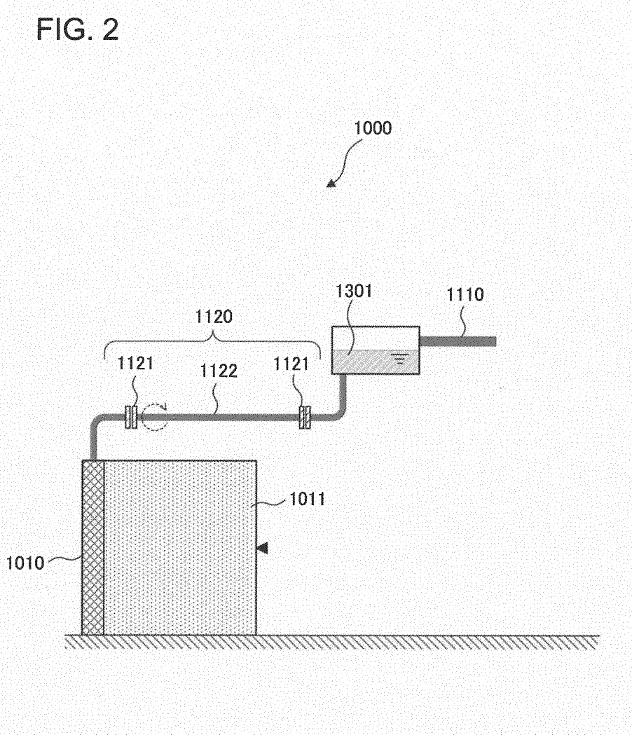

FIG. 2 is a side view illustrating a configuration of a part of the phase-change cooling device 1000 according to the present example embodiment. The heat receiving unit 1010 includes a plurality of evaporators that are thermally connected with heat sources and stores refrigerant, and constitutes a cooling unit in which the plurality of evaporators are located in a vertical direction. The cooling unit is disposed in an electronic equipment rack 1011 to house electronic appliances that serve as the heat sources. More specifically, for example, a plurality of servers that serve as heat sources are disposed stacked in the electronic equipment rack 1011. The cooling unit that serves as the heat receiving unit 1010 can be loaded onto the rear door and the like of the electronic equipment rack 1011. The triangular sign (▴) in the following figures indicates the front side of the electronic equipment rack 1011, that is, the intake side of the cooling air.

A part of the secondary tube (secondary liquid tube) 1120 is a bendable flexible tube 1122. The flexible tube 1122 connects the refrigerant liquid reservoir 1301 with the heat receiving unit 1010 in the electronic equipment rack 1011 by means of flanges 1121 and the like. The flexible tube 1122 can be disposed on a plane, for example, on a plane approximately level to the top board surface of the electronic equipment rack 1011. This arrangement frees the flexible tube 1122 from a twist around the rotation axis indicated by the dashed arrow in FIG. 2 when opening and closing the rear door of the electronic equipment rack 1011. This makes it possible to prevent the flexible tube 1122 from breaking due to metal fatigue that is caused by the opening and closing of the rear door.

The flexible tube 1122 can be configured such that the end portion of the flexible tube 1122 on the side where the secondary tube 1120 is connected with the refrigerant liquid reservoir 1301 is located above the other end portion of the flexible tube 1122 on the side where the secondary tube 1120 is connected with the heat receiving unit 1010. Sloping the secondary tube 1120 as described above facilitates the natural circulation of the refrigerant liquid by the effect of the force of gravity.

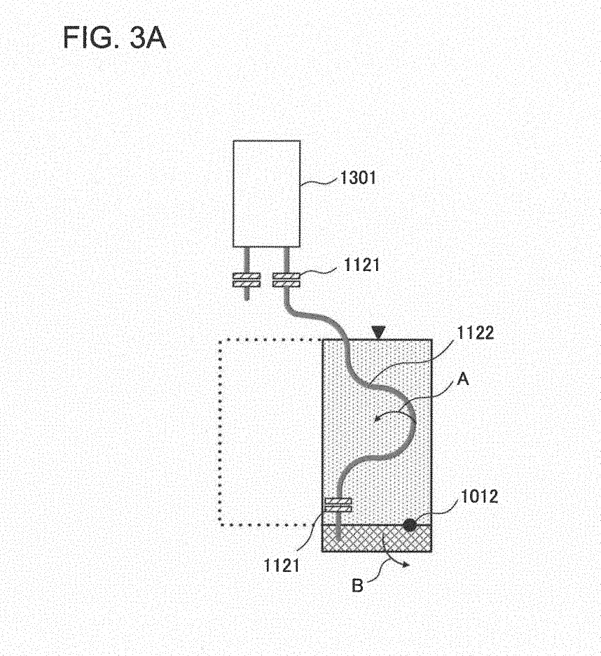

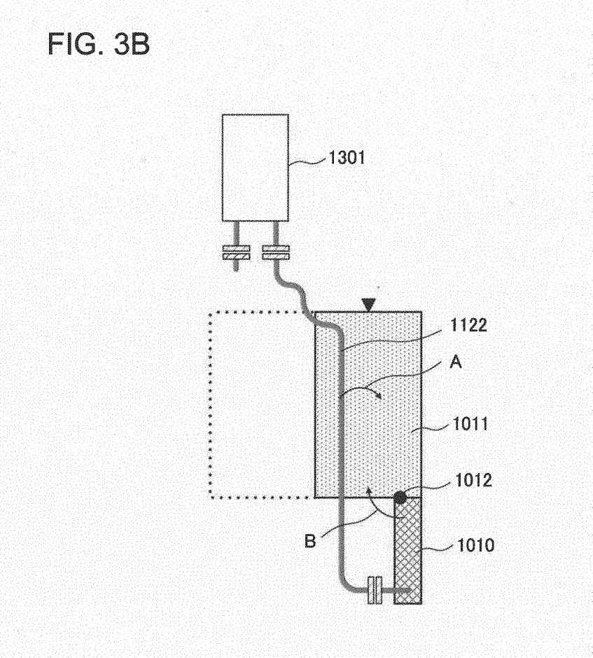

FIG. 3A and FIG. 3B are top views illustrating the configurations of a part of the phase-change cooling device 1000 according to the present example embodiment. FIG. 3A illustrates a state in which the rear door of the electronic equipment rack 1011 is closed, and FIG. 3B illustrates a state in which the rear door is open. The flexible tube 1122 is disposed on a plane, for example, on the top board surface of the electronic equipment rack 1011, and configured to be movable within this plane. In other words, as illustrated in the figure, the flexible tube 1122 can move approximately horizontally to the top board surface of the electronic equipment rack 1011 as indicated by arrow A in the figures, with the movement of the rear door, indicated by arrow B, rotating around a hinge 1012 of the rear door serving as a rotational axis. Consequently, the length of the flexible tube 1122 is such that the tension is not added with the rear door of the electronic equipment rack 1011 open, and can be determined taking into consideration the material for and the thickness of the flexible tube 1122.

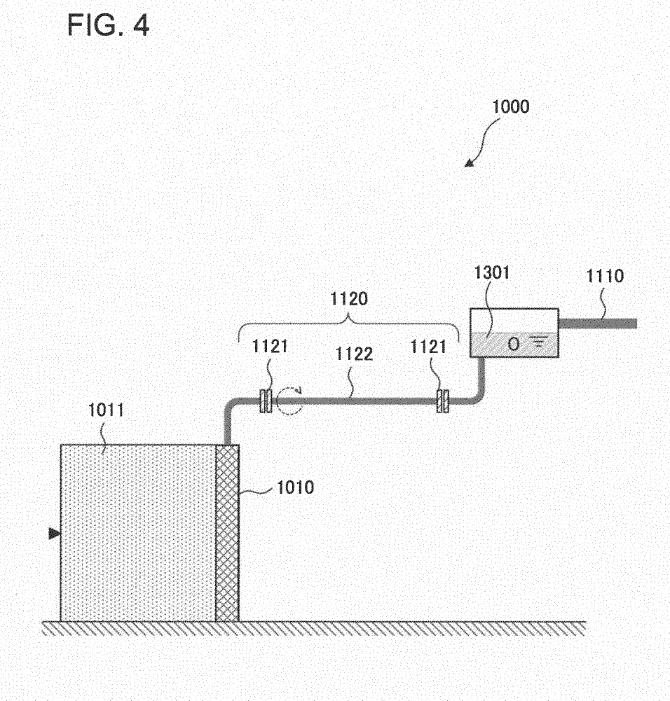

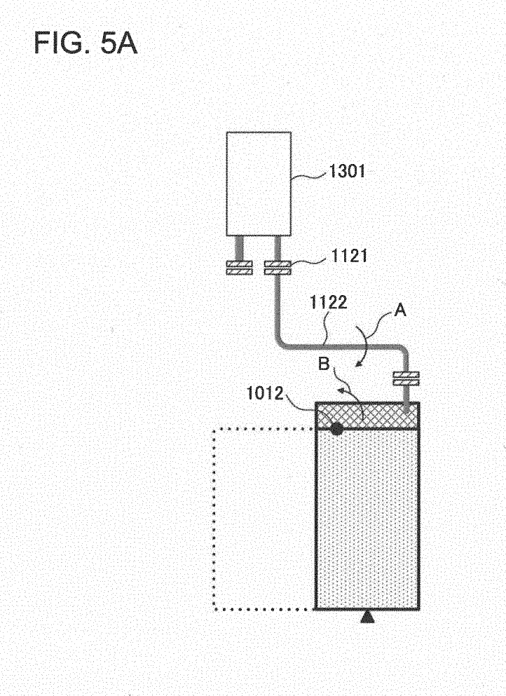

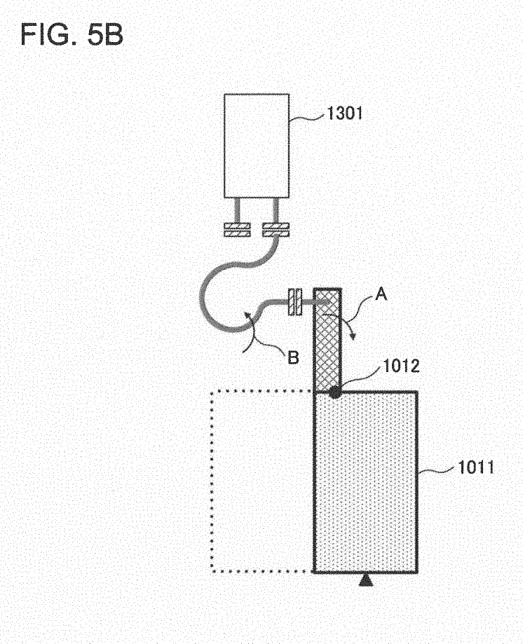

In FIG. 2, FIG. 3A, and FIG. 3B, a configuration is described in which the refrigerant liquid reservoir 1301 serving as the refrigerant retaining unit 1300 is located above the heat receiving unit 1010 and on the front side of the electronic equipment rack 1011. Alternatively, as illustrated in FIG. 4, FIG. 5A, and FIG. 5B, the refrigerant liquid reservoir 1301 may be located above the heat receiving unit 1010 and on the side where the cooling unit constituting the heat receiving unit 1010 of the electronic equipment rack 1011 is disposed. In other words, the refrigerant liquid reservoir 1301 can be disposed behind the electronic equipment rack 1011. In this case, the flexible tube 1122 is extended with the rear door of the electronic equipment rack 1011 closed (FIG. 5A). This makes it possible to form easily a configuration in which the secondary tube 1120 is sloped to promote the natural circulation of the refrigerant liquid.

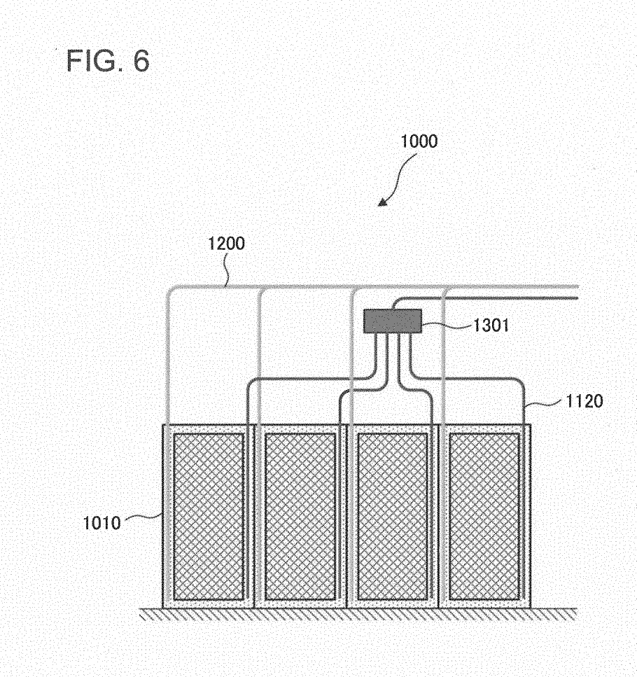

The above description has been made with respect to the configuration of the phase-change cooling device 1000 that includes single heat receiving unit 1010. Alternatively, as illustrated in FIG. 6, the phase-change cooling device 1000 may be configured to include a plurality of heat receiving units 1010 and a refrigerant liquid reservoir 1301 connected with the plurality of heat receiving units 1010 by a plurality of secondary tubes 1120 respectively. In this case, the refrigerant liquid reservoir 1301 can store the refrigerant liquid temporarily, which makes it possible to distribute the refrigerant liquid equally to the plurality of heat receiving units 1010.

In the above description, the refrigerant retaining unit 1300 has been described as the refrigerant liquid reservoir 1301 to store the refrigerant liquid. Alternatively, the refrigerant retaining unit may be a vapor convergence unit in which the streams of the refrigerant vapor converge. In this case, the primary tube is a primary vapor tube through which the refrigerant vapor mainly flows, and the secondary tube is a secondary vapor tube through which the refrigerant vapor mainly flows.

Next, a method of manufacturing the phase-change cooling device according to the present example embodiment will be described.

In the method of manufacturing the phase-change cooling device according to the present example embodiment, first, a heat receiving unit configured to receive heat from a heat source and contain refrigerant is disposed, and a condensing unit configured to condense and liquefy refrigerant vapor of the refrigerant evaporated in the heat receiving unit and generate refrigerant liquid is disposed on the ceiling panel. A refrigerant retaining unit configured to retain the refrigerant is disposed below the condensing unit and above the heat receiving unit. The refrigerant retaining unit is connected with the condensing unit by a primary tube, and the refrigerant retaining unit is connected with the heat receiving unit by a secondary tube including a bendable flexible tube. Through the above processes, the phase-change cooling device according to the present example embodiment has been completed.

As mentioned above, the phase-change cooling device 1000 according to the present example embodiment is configured to include a refrigerant transporting structure connecting the heat receiving unit 1010 with the condensing unit 1020, the refrigerant transporting structure including the refrigerant retaining unit 1300 and the secondary tube 1120 including a flexible tube.

The refrigerant vapor evaporated by receiving heat in the heat receiving unit 1010 is condensed and liquefied in the condensing unit 1020 into refrigerant liquid and flows back to the heat receiving unit 1010. Because the refrigerant retaining unit 1300 stores the refrigerant temporarily, it can compensate for the excess or deficiency of the refrigerant flowing back to the heat receiving unit 1010. Consequently, according to the phase-change cooling device of the present example embodiment, it is possible to cool a heat source efficiently employing a natural-circulation type phase-change cooling system without the increase in device cost and maintenance cost. In addition, because the phase-change cooling device 1000 according to the present example embodiment is configured to include the flexible tube, it is possible to increase the degree of freedom in installing the phase-change cooling device 1000; for example, it becomes possible to load the heat receiving unit in moving parts of the electronic equipment rack.

### A Second Example Embodiment

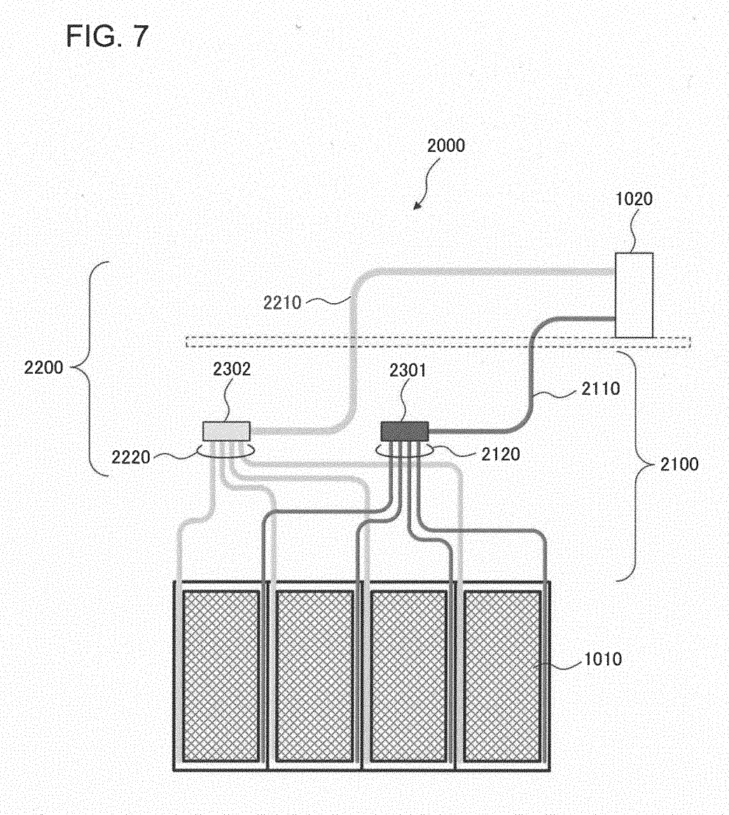

Next, a second example embodiment of the present invention will be described. FIG. 7 illustrates a configuration of a phase-change cooling device 2000 according to the present example embodiment.

The phase-change cooling device 2000 according to the present example embodiment differs from the phase-change cooling device 1000 according to the first example embodiment in including a plurality of heat receiving units 1010, and including a refrigerant liquid reservoir 2301 configured to store refrigerant liquid and a vapor convergence unit 2302 in which streams of refrigerant vapor converge that serve as a refrigerant retaining unit. As illustrated in FIG. 7, the refrigerant liquid reservoir 2301 and the vapor convergence unit 2302 are located below the condensing unit 1020 and above the heat receiving unit 1010.

The configuration of the phase-change cooling device 2000 according to the present example embodiment will be described further in detail. The phase-change cooling device 2000 according to the present example embodiment includes a plurality of heat receiving units 1010, a condensing unit 1020, and a refrigerant transporting structure connecting the heat receiving units 1010 with the condensing unit 1020. The refrigerant transporting structure includes a refrigerant liquid transporting structure 2100 configured to transport refrigerant liquid and a refrigerant vapor transporting structure 2200 configured to transport refrigerant vapor.

The refrigerant liquid transporting structure 2100 includes a refrigerant liquid reservoir 2301, a primary liquid tube 2110 connecting the refrigerant liquid reservoir 2301 with the condensing unit 1020, and a secondary liquid tube 2120 connecting the refrigerant liquid reservoir 2301 with each of the plurality of heat receiving units 1010 and including a bendable flexible tube. In the primary liquid tube 2110 and the secondary liquid tube 2120 flows mainly refrigerant liquid.

The refrigerant vapor transporting structure 2200 includes a vapor convergence unit 2302, a primary vapor tube 2210 connecting the vapor convergence unit 2302 with the condensing unit 1020, and a secondary vapor tube 2220 connecting the vapor convergence unit 2302 with each of the plurality of heat receiving units 1010 and including a bendable flexible tube. In the primary vapor tube 2210 and the secondary vapor tubes 2220 flows mainly refrigerant vapor.

Because the refrigerant liquid pools in the refrigerant liquid reservoir 2301, the refrigerant liquid is supplied from the refrigerant liquid reservoir 2301 to each of the heat receiving units 1010 in just proportion depending on the amount of the refrigerant liquid having decreased due to vaporization by receiving heat in each of the heat receiving units 1010. That is to say, it becomes possible to supply the refrigerant liquid with the quantity corresponding to the load of each heat receiving unit 1010 to each of the heat receiving units 1010 without using driving parts, sensing components, and the like.

Because the streams of the refrigerant vapor generated in the plurality of heat receiving units 1010 are converged in the vapor convergence unit 2302, it is possible to decrease the pressure loss due to branching. As a result, it is possible to achieve an efficient cooling by the natural-circulation type phase-change cooling system without degrading the cooling performance, even though the plurality of heat receiving units 1010 are included.

As mentioned above, the phase-change cooling device 2000 according to the present example embodiment is configured to include the refrigerant liquid reservoir 2301 and the vapor convergence unit 2302. This makes it possible to cool a heat source efficiently employing a natural-circulation type phase-change cooling system without the increase in device cost and maintenance cost. In addition, the phase-change cooling device 2000 according to the present example embodiment is configured to include the secondary liquid tubes 2120 and the secondary vapor tubes 2220 that include the flexible tubes. This makes it possible to increase the degree of freedom in installing the phase-change cooling device 2000; for example, it becomes possible to load the heat receiving unit in moving parts of the electronic equipment rack.

Next, a specific configuration of the phase-change cooling device 2000 according to the present example embodiment will be described.

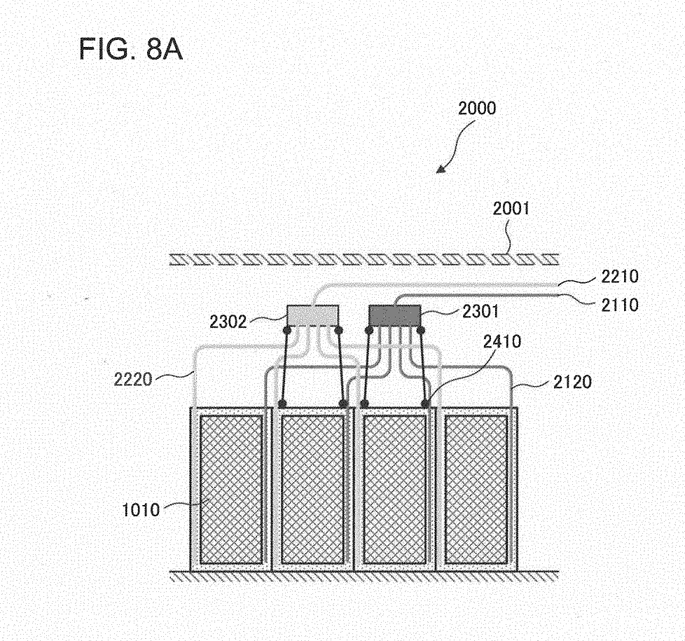

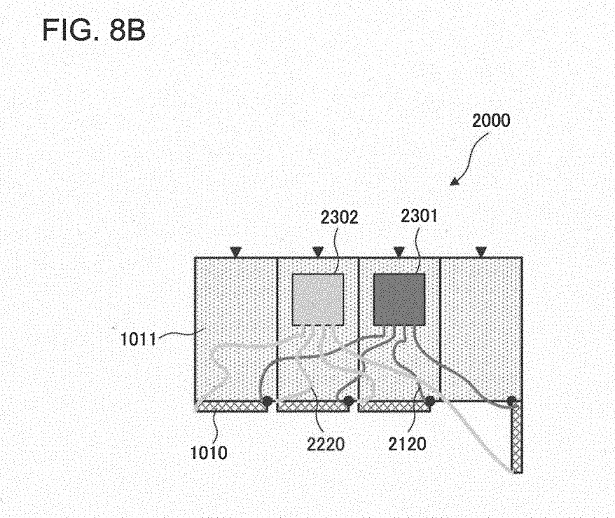

FIG. 8A and FIG. 8B illustrate a specific configuration of the phase-change cooling device 2000. FIG. 8A is a front view, and FIG. 8B is a top view.

The heat receiving unit 1010 includes a plurality of evaporators thermally connected with heat sources and storing refrigerant, and constitutes a cooling unit in which the plurality of evaporators are disposed in a vertical direction. The cooling unit that serves as the heat receiving unit 1010 is loaded onto the rear door of the electronic equipment rack 1011. In addition, as illustrated in FIG. 8A and FIG. 8B, a plurality of electronic equipment racks 1011 are arranged in a row, and the refrigerant liquid reservoir 2301 and the vapor convergence unit 2302 that serve as refrigerant retaining units are disposed above the plurality of electronic equipment racks 1011 arranged in a row.

More specifically, the refrigerant liquid reservoir 2301 and the vapor convergence unit 2302 can be mounted on the top board of the electronic equipment rack 1011 using an attaching structure 2410. The refrigerant liquid reservoir 2301 and the vapor convergence unit 2302 are connected with the plurality of heat receiving units 1010 loaded in the plurality of electronic equipment racks 1011 by means of the secondary liquid tubes 2120 and the secondary vapor tubes 2220, respectively. The configuration makes it possible to use mechanism elements such as a screw hole included in the electronic equipment rack 1011. This makes it possible to mount easily the refrigerant liquid reservoir 2301 and the vapor convergence unit 2302 with the electronic equipment racks 1011 having already been installed. Alternatively, the refrigerant liquid reservoir 2301 and the vapor convergence unit 2302 may be disposed above the electronic equipment racks 1011 by fixing them to the ceiling panel 2001 using a ceiling-suspended structure or the like.

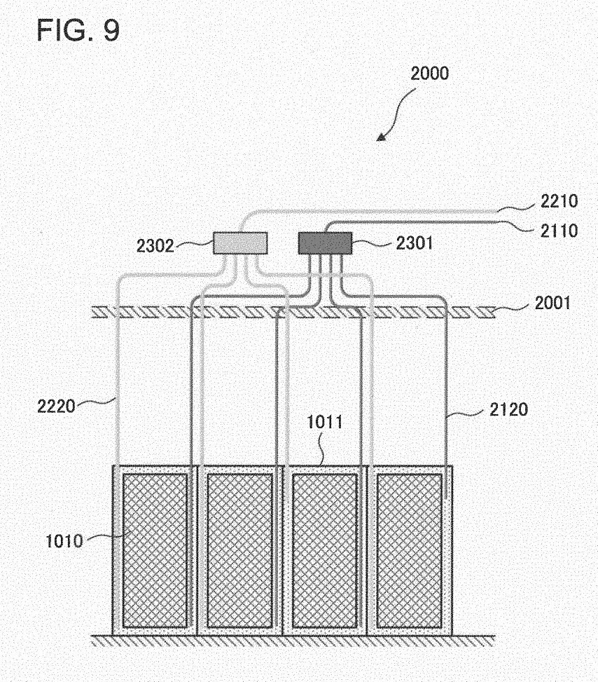

As illustrated in FIG. 9, the phase-change cooling device 2000 may be also configured to have the refrigerant liquid reservoir 2301 and the vapor convergence unit 2302 that serve as refrigerant retaining units disposed on the ceiling panel 2001 on which the condensing unit 1020 is disposed. The configuration makes it possible to install the refrigerant liquid reservoir 2301 and the vapor convergence unit 2302 together with installing the primary liquid tube 2110, the primary vapor tube 2210, and the condensing unit 1020 when constructing a building. As a result, it becomes easy to install additional electronic equipment racks 1011 because all you need to do is connect the secondary liquid tubes 2120 and the secondary vapor tubes 2220 to respective electronic equipment racks 1011 when installing the electronic equipment racks 1011.

In this case, switching mechanisms such as a valve can be provided for connecting ports that are connected with the secondary liquid tubes 2120 and the secondary vapor tubes 2220 and included in the refrigerant liquid reservoir 2301 and the vapor convergence unit 2302 respectively. This eliminates the need for connecting the electronic equipment racks 1011 to all the connection ports, which enables the maintenance and replacement of the electronic equipment rack 1011.

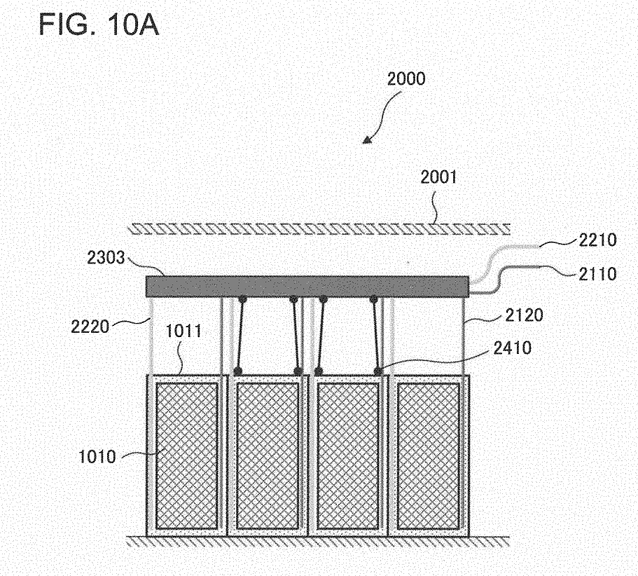

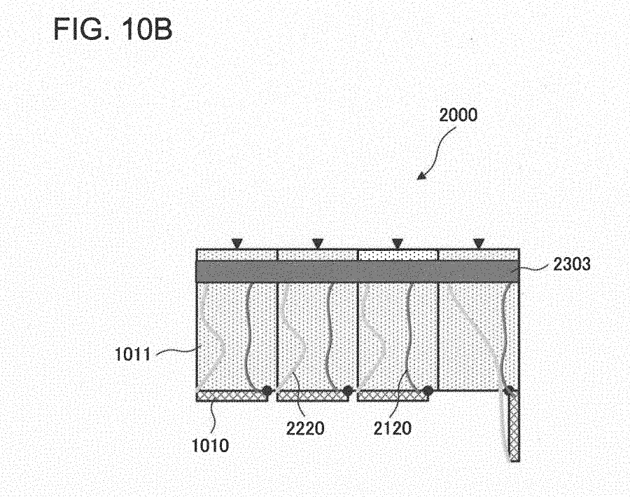

In the above description, the phase-change cooling device 2000 is configured to have the refrigerant liquid reservoir 2301 and the vapor convergence unit 2302 that serve as the refrigerant retaining units disposed above the plurality of electronic equipment racks 1011. Alternatively, as illustrated in FIG. 10A and FIG. 10B, the phase-change cooling device 2000 may be configured to have a combined refrigerant retaining unit 2303 that serves as the refrigerant retaining unit disposed above the plurality of electronic equipment racks 1011. The combined refrigerant retaining unit 2303 is configured in which the refrigerant liquid is stored and streams of refrigerant vapor converge.

The combined refrigerant retaining unit 2303 retains both the refrigerant vapor and the refrigerant liquid, and mixed refrigerant liquid that is liquid-state refrigerant mixed in the refrigerant vapor flows out from the combined refrigerant retaining unit 2303 to the secondary liquid tubes 2120 together with the refrigerant liquid. This enables the mixed refrigerant liquid to be removed from the refrigerant vapor; therefore, it is possible to prevent an increase in fluid resistance to the refrigerant vapor that causes the degradation of the cooling performance.

### A Third Example Embodiment

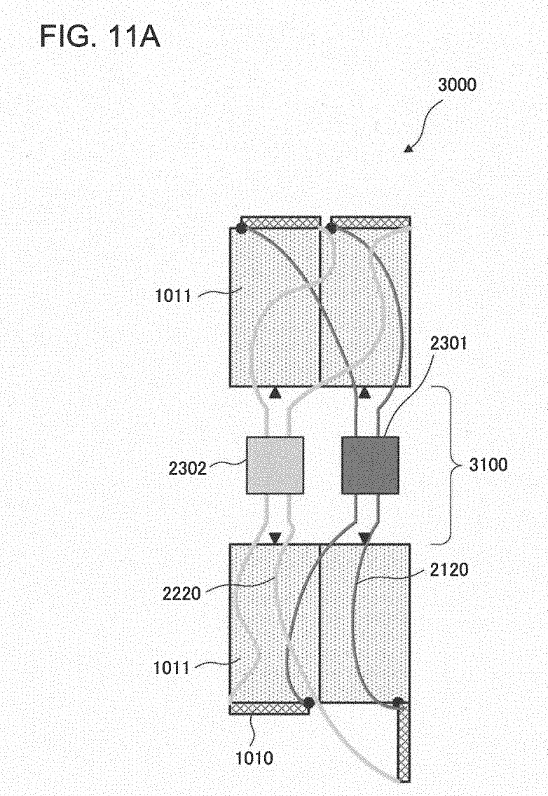

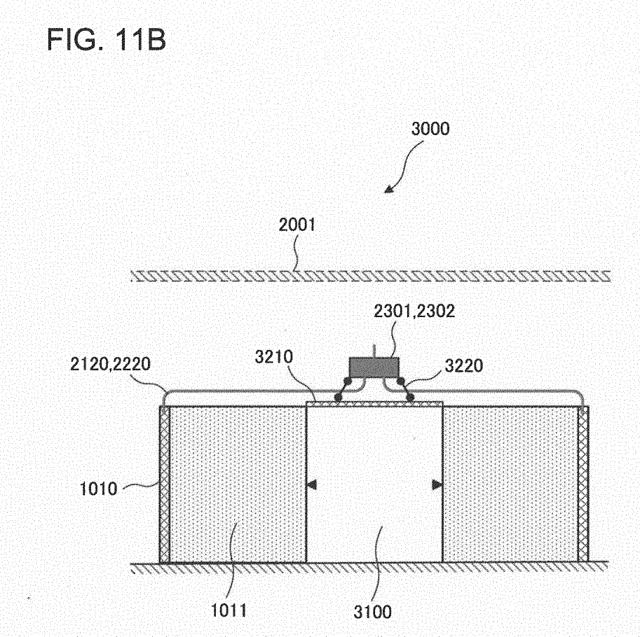

Next, a third example embodiment of the present invention will be described. FIG. 11A and FIG. 11B illustrate a phase-change cooling device 3000 according to the present example embodiment. FIG. 11A is a top view, and FIG. 11B is a side view.

The phase-change cooling device 3000 according to the present example embodiment includes a plurality of heat receiving units 1010, the refrigerant liquid reservoir 2301 configured to store the refrigerant liquid and the vapor convergence unit 2302 in which streams of the refrigerant vapor converge that serve as the refrigerant retaining units.

The heat receiving unit 1010 includes a plurality of evaporators thermally connected with heat sources and storing refrigerant, and constitutes a cooling unit in which the plurality of evaporators are disposed in a vertical direction. The cooling unit that serves as the heat receiving unit 1010 is loaded on the rear door of the electronic equipment rack 1011.

The above-described configuration is similar to that of the phase-change cooling device 2000 according to the second example embodiment. In the phase-change cooling device 3000 according to the present example embodiment, a plurality of electronic equipment racks 1011 are arranged so as to face each other across an inter-rack aisle 3100. The refrigerant liquid reservoir 2301 and the vapor convergence unit 2302 that serve as the refrigerant retaining units are disposed above the inter-rack aisle 3100. The inter-rack aisle 3100 includes an aisle through which the cooling air introduced from the front of the electronic equipment rack 1011 flows (a cold aisle) and an aisle through which the air with waste heat exhausted from the back side of the electronic equipment rack 1011 flows (a hot aisle). FIG. 11A and FIG. 11B illustrate an example in which the inter-rack aisle 3100 is the cold aisle; however, the refrigerant liquid reservoir 2301 and the vapor convergence unit 2302 may be disposed above the inter-rack aisle 3100 that serves as the hot aisle.

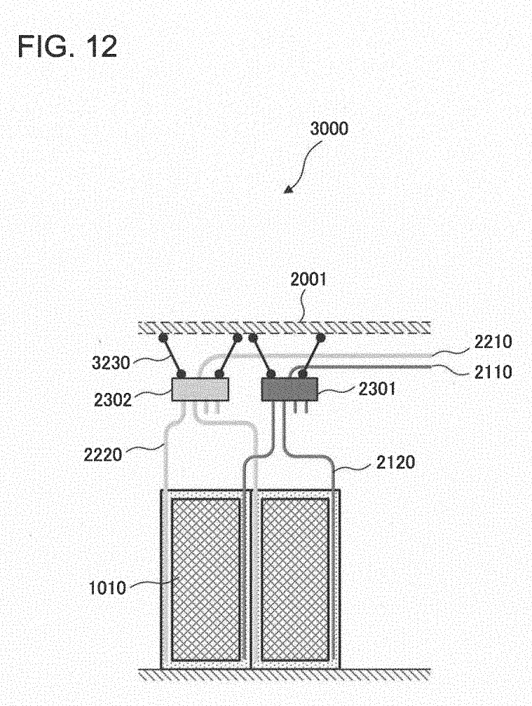

More specifically, as illustrated in FIG. 11B, the refrigerant liquid reservoir 2301 and the vapor convergence unit 2302 that serve as the refrigerant retaining unit can be disposed on a support board 3210 connecting the electronic equipment racks 1011 disposed face-to-face. The refrigerant liquid reservoir 2301 and the vapor convergence unit 2302 are mounted on the support board 3210 using an attaching structure 3220 or the like and connected with respective secondary liquid tubes 2120 and respective secondary vapor tubes 2220 of the plurality of electronic equipment racks 1011 disposed face-to-face. Alternatively, as illustrated in FIG. 12, the refrigerant liquid reservoir 2301 and the vapor convergence unit 2302 may be attached to the ceiling panel 2001 using a ceiling-suspended structure 3230 or the like.

As mentioned above, the phase-change cooling device 3000 according to the present example embodiment is configured to include the refrigerant liquid reservoir 2301 and the vapor convergence unit 2302. This makes it possible to cool a heat source efficiently employing a natural-circulation type phase-change cooling system without the increase in device cost and maintenance cost. In addition, the phase-change cooling device 3000 according to the present example embodiment is configured to include the secondary liquid tubes 2120 and the secondary vapor tubes 2220 that include the flexible tubes. This makes it possible to increase the degree of freedom in installing the phase-change cooling device 3000; for example, it becomes possible to load the heat receiving unit in moving parts of the electronic equipment rack.

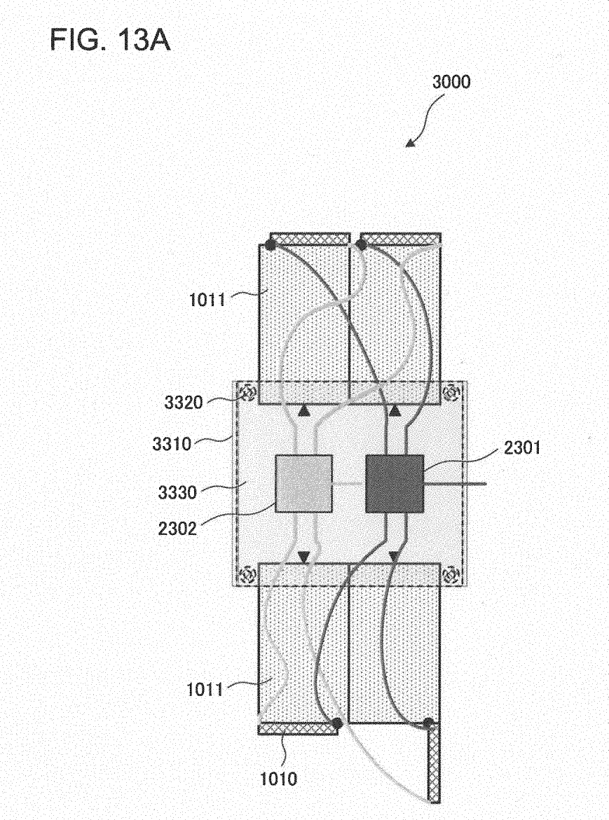

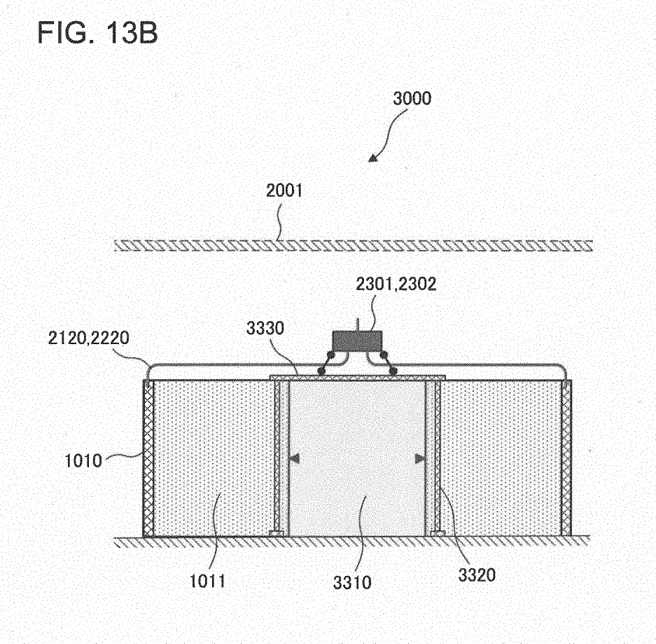

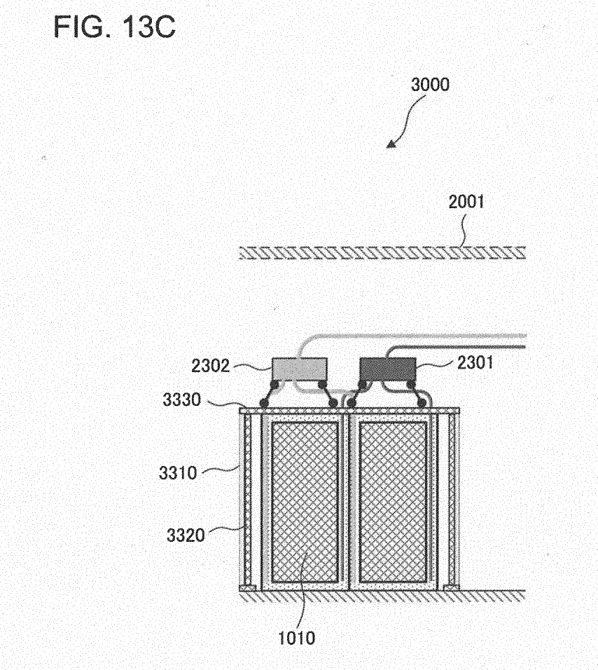

FIG. 13A, FIG. 13B, and FIG. 13C illustrate another configuration of the phase-change cooling device 3000. FIG. 13A is a top view, FIG. 13B is a side view, and FIG. 13C is a front view. As illustrated in the figures, the refrigerant liquid reservoir 2301 and the vapor convergence unit 2302 that serve as the refrigerant retaining units can be located on a top board 3330 supported by a support pole 3320 for holding up a partition wall 3310 of the inter-rack aisle 3100.

The partition wall 3310 includes an aisle capping or the like that is provided for the cold aisle or the hot aisle in order to prevent the cooling air introduced from the front of the electronic equipment rack 1011 from mixing with the warm air exhausted from the exhaust side of the electronic equipment racks 1011, for example. Since the aisle capping is configured to cover with a curtain made of vinyl or the like by the support pole 3320, it is possible to attach the top board 3330 to the support pole 3320 together with the curtain. This makes it possible to maintain strength to support the refrigerant liquid reservoir 2301 and the vapor convergence unit 2302.

The configuration makes it possible to achieve an efficient air flow in the building by means of the partition wall 3310 and promote efficient heat exhaust by using the phase-change cooling system. The synergistic effect of these advantages makes it possible to reduce drastically the power consumption for air conditioning of the building in which the electronic equipment rack 1011 is installed.

Hereinabove, the present invention has been described using the above-described example embodiments as exemplary examples. The present invention, however, is not limited to the above-described example embodiments. In other words, various aspects that can be recognized by those skilled in the art can be applied to the present invention within the scope of the invention.

This application is based upon and claims the benefit of priority from Japanese Patent Application No. 2014-196175, filed on Sep. 26, 2014, the disclosure of which is incorporated herein in its entirety by reference.

### REFERENCE SIGNS LIST

1000, 2000, 3000 phase-change cooling device
1010 heat receiving unit
1011 electronic equipment rack
1012 hinge
1020 condensing unit
1110 primary tube
1120 secondary tube
1121 flange
1122 flexible tube
1200 vapor tube
1300 refrigerant retaining unit
1301, 2301 refrigerant liquid reservoir
2001 ceiling panel
2100 refrigerant liquid transporting structure
2200 refrigerant vapor transporting structure
2110 primary liquid tube
2120 secondary liquid tube
2210 primary vapor tube
2220 secondary vapor tube
2302 vapor convergence unit
2303 combined refrigerant retaining unit
2410 attaching structure
3100 inter-rack aisle
3210 support board
3220 attaching structure
3230 suspension structure
3310 partition wall
3320 support pole
3330 top board

1. A cooling device, comprising:
a heat receiving unit configured to receive heat;
a condensing unit configured to release heat; and
a refrigerant intermediary unit configured to connect the heat receiving unit with the condensing unit, and transport refrigerant circulating between the heat receiving unit and the condensing unit,
wherein the refrigerant intermediary unit includes
a refrigerant retaining unit configured to retain the refrigerant,
a primary tube connecting the refrigerant retaining unit with the condensing unit, and
a secondary tube connecting the refrigerant retaining unit with the heat receiving unit and including a bendable tube.

2. The cooling device according to claim 1, wherein the refrigerant retaining unit is located below the condensing unit and above the heat receiving unit.

3. The cooling device according to claim 1,
wherein the bendable tube is located on a plane and is movable within the plane.

4. The cooling device according to claim 1,
wherein the refrigerant retaining unit is a refrigerant liquid reservoir configured to store refrigerant liquid.

5. The cooling device according to claim 4,
wherein the bendable tube is such that an end portion of the bendable tube on a side where the secondary tube is connected with the refrigerant liquid reservoir is located above another end portion of the bendable tube on a side where the secondary tube is connected with the heat receiving unit.

6. The cooling device according to claim 1,
wherein the refrigerant retaining unit is a vapor convergence unit in which streams of refrigerant vapor contained in the refrigerant converge.

7. The cooling device according to claim 1,
wherein the refrigerant retaining unit is a combined refrigerant retaining unit in which refrigerant liquid contained in the refrigerant is stored and streams of refrigerant vapor contained in the refrigerant converge.

8. The cooling device according to claim 1,
wherein the condensing unit is located on a ceiling panel, and the refrigerant retaining unit is located above the ceiling panel.

9. The cooling device according to claim 1,
wherein the heat receiving unit includes a plurality of evaporators thermally connected with heat sources and storing the refrigerant, and constitutes a cooling unit in which the plurality of evaporators are located in a vertical direction, and
the cooling unit is disposed in an electronic equipment rack for housing electronic appliances that serve as the heat sources.

10. The cooling device according to claim 9,
wherein the refrigerant retaining unit is located in a position above the heat receiving unit, and located on one of a front side of the electronic equipment rack and a side on which the cooling unit of the electronic equipment rack is located.

11. The cooling device according to claim 9,
wherein the electronic equipment rack includes a plurality of racks arranged in a row, and
the refrigerant retaining unit is located above the plurality of racks arranged in a row.

12. The cooling device according to claim 9,
wherein the electronic equipment rack includes a plurality of racks arranged so as to face each other across an inter-rack aisle, and
the refrigerant retaining unit is disposed above the inter-rack aisle.

13. The cooling device according to claim 12,
wherein the refrigerant retaining unit is located on a support board connecting the electronic equipment racks disposed face-to-face.

14. The cooling device according to claim 12,
wherein the condensing unit is located on a ceiling panel, and
the refrigerant retaining unit is attached to the ceiling panel.

15. The cooling device according to claim 12,
wherein the refrigerant retaining unit is located on a top board supported by a support pole for holding up a partition wall of the inter-rack aisle.

16. A method of manufacturing a cooling device, comprising:
disposing a heat receiving unit configured to receive heat;
disposing a condensing unit configured to release heat on a ceiling panel;
disposing a refrigerant retaining unit configured to retain refrigerant below the condensing unit and above the heat receiving unit;
connecting the refrigerant retaining unit with the condensing unit by a primary tube; and
connecting the refrigerant retaining unit with the heat receiving unit by a secondary tube including a bendable tube.

17. The cooling device according to claim 2,
wherein the bendable tube is located on a plane and is movable within the plane.

18. The cooling device according to claim 2,
wherein the refrigerant retaining unit is a refrigerant liquid reservoir configured to store refrigerant liquid.

19. The cooling device according to claim 3,
wherein the refrigerant retaining unit is a refrigerant liquid reservoir configured to store refrigerant liquid.

20. The cooling device according to claim 2,
wherein the refrigerant retaining unit is a vapor convergence unit in which streams of refrigerant vapor contained in the refrigerant converge.
